(19) United States
(12) Patent Application Publication
(10) Pub. No.: US 2025/0151576 A1
(43) Pub. Date: May 8, 2025

(54) ORGANIC LIGHT-EMITTING DISPLAY, HEAD-MOUNTED DISPLAY INCLUDING THE SAME, AND METHOD OF MANUFACTURING THE SAME

(71) Applicant: SAMSUNG ELECTRONICS CO., LTD., Suwon-si (KR)

(72) Inventors: Jisoo Ham, Suwon-si (KR); Kyunglyong Kang, Suwon-si (KR); Jungu Kang, Suwon-si (KR); Youngmok Kim, Suwon-si (KR); Yongsang Jeong, Suwon-si (KR)

(21) Appl. No.: 18/764,637

(22) Filed: Jul. 5, 2024

(30) Foreign Application Priority Data
Nov. 8, 2023 (KR) 10-2023-0153938

(51) Int. Cl. H10K 59/80; G02B 27/01; H10K 59/122; H10K 102/00

(52) U.S. Cl. CPC H10K 59/8723; G02B 27/0172; H10K 59/122; H10K 2102/351

(57) ABSTRACT

An organic light-emitting display includes a substrate including a first pixel region, a second pixel region, and a division region disposed between the first pixel region and the second pixel region, an insulating layer disposed on the substrate and including a recess disposed in the division region, the insulating layer including a first inner side wall defining a first portion of the recess and a second inner side wall extending from the first inner side wall, defining a second portion of the recess, and having a curved shape, a plurality of pixel electrodes disposed on the insulating layer, a spacer disposed on a side wall of each of the pixel electrodes and the first inner side wall, and a first organic emission layer disposed on the spacer, wherein the spacer includes a material having an etch selectivity different than an etch selectivity of the insulating layer.

### CROSS-REFERENCE TO RELATED APPLICATION

This application is based on and claims priority under 35 U.S.C. § 119 to Korean Patent Application No. 10-2023-0153938, filed on Nov. 8, 2023, in the Korean Intellectual Property Office, the disclosure of which is incorporated by reference herein in its entirety.

### BACKGROUND

### 1. Technical Field

The inventive concept relates to an organic light-emitting display, a head-mounted display including the organic light-emitting display, and a method of manufacturing the organic light-emitting display.

### 2. Discussion of Related Art

As the information society has developed, various demands have emerged for display devices capable of displaying images. Accordingly, various types of display devices have been developed, such as liquid crystal displays (LCD), plasma display panels (PDP), and organic light-emitting displays (OLED).

The organic light-emitting display is a self-emitting display type. The organic light-emitting display has improved characteristics, such as a viewing angle or a contrast, as compared to a liquid crystal display. Also, the organic light-emitting display typically omits a backlight so as to have reduced weight and thickness, and lowered power consumption. In addition, the organic light-emitting display may be driven by a direct current-low voltage, and may have a high response speed, and low manufacturing costs.

The organic light-emitting display may include an organic light-emitting diode on silicon (OLEDoS) formed by using a wafer-based semiconductor process. Also, an organic emission layer generating red light, an organic emission layer generating green light, and an organic emission layer generating blue light may be vertically stacked on a wafer. A white light may be generated when charge generation layers simultaneously inject an electron and a hole to the organic emission layers.

### SUMMARY

The inventive concept provides an organic light-emitting display, in which charge generation layers may be disconnected between adjacent cells and a cathode may extend between the adjacent cells, and a method of manufacturing the organic light-emitting display.

The inventive concept provides an organic light-emitting display having improved reliability and a method of manufacturing the organic light-emitting display.

Technical objectives to be achieved by the inventive concept are not limited by the disclosure. Other technical objectives that are not mentioned herein would be clearly understood by one of ordinary skill in the art based on the description of the inventive concept.

According to an aspect of the inventive concept, there is provided an organic light-emitting display including a substrate including a first pixel region, a second pixel region spaced apart from the first pixel region in a horizontal direction, and a division region disposed between the first pixel region and the second pixel region, an insulating layer disposed on the substrate and including a recess disposed in the division region, the insulating layer including a first inner side wall defining a first portion of the recess and a second inner side wall extending from the first inner side wall, defining a second portion of the recess, and having a curved shape, a plurality of pixel electrodes disposed on the insulating layer, and including a first pixel electrode in the first pixel region and a second pixel electrode in the second pixel region, a spacer disposed on a side wall of each of the pixel electrodes and the first inner side wall of the insulating layer, and a first organic emission layer disposed on the spacer, wherein the spacer includes a material having an etch selectivity different than an etch selectivity of the insulating layer.

According to another aspect of the inventive concept, there is provided an organic light-emitting display including a substrate including a first pixel region, a second pixel region spaced apart from the first pixel region in a horizontal direction, and a division region disposed between the first pixel region and the second pixel region, an insulating layer disposed on the substrate and including a recess disposed in the division region, the insulating layer including a first inner side wall defining a first portion of the recess and having a straight-line shape and a second inner side wall extending from the first inner side wall, defining a second portion of the recess, and having a curved shape, a plurality of pixel electrodes disposed on the insulating layer, including a first pixel electrode disposed in the first pixel region and a second pixel electrode disposed in the second pixel region, a spacer disposed on a side wall of each of the pixel electrodes and the first inner side wall of the insulating layer, a first organic emission layer disposed on the spacer in the first pixel region and the second pixel region, a first cavity surrounded by the second inner side wall, and a second cavity disposed between the first organic emission layer in the first pixel region and the first organic emission layer in the second pixel region, wherein the first cavity and the second cavity are connected to each other.

According to another aspect of the inventive concept, there is provided an organic light-emitting display including a substrate including a first pixel region, a second pixel region spaced apart from the first pixel region in a horizontal direction, and a division region disposed between the first pixel region and the second pixel region, a circuit device layer disposed on the substrate, an insulating layer disposed on the circuit device layer and including a recess in the division region, the recess defined by a first inner side wall of the insulating layer adjacent to a top surface of the insulating layer and a second inner side wall of the insulating layer extending from the first inner side wall, a plurality of pixel electrodes disposed on the insulating layer, and including a first pixel electrode in the first pixel region and a second pixel electrode in the second pixel region, a spacer disposed on a side wall of each of the pixel electrodes and the first inner side wall of the insulating layer, a first organic emission layer disposed on a top surface and a side wall of the spacer, the first organic emission layer continually extending in the horizontal direction in the first pixel region and the second pixel region and disconnected in the division region, a second organic emission layer disposed on the first organic emission layer, the second organic emission layer disposed on a top surface and a side surface of the first organic emission layer, a third organic emission layer disposed on the second organic emission layer, the third organic emission layer continually extending from the first pixel region to the second pixel region, and a common electrode disposed on the third organic emission layer, the common electrode continually extending from the first pixel region to the second pixel region, wherein the first inner side wall has a straight-line shape, the second inner side wall has a concave shape, and the spacer includes a material having an etch selectivity different than an etch selectivity of the insulating layer.

According to the inventive concept, an insulating layer disposed on a substrate may include a recess. Thus, at least a portion of a first organic emission layer and at least a portion of a second organic emission layer may be disposed in the recess, and each of the first organic emission layer and the second organic emission layer may be disconnected in a division region. Also, a common electrode formed on a third organic emission layer may continually extend from a first pixel region to a second pixel region, and through a division region. Thus, the reliability of the organic light-emitting display may be improved.

### BRIEF DESCRIPTION OF THE DRAWINGS

Embodiments will be more clearly understood from the following detailed description taken in conjunction with the accompanying drawings in which:

FIG. 1 is an exploded perspective view of an organic light-emitting display according to an embodiment;

FIG. 2 is a cross-sectional view of the organic light-emitting display taken along line I-I′ of FIG. 1;

FIG. 3 is an enlarged view of region PP of FIG. 2;

FIG. 4 is an enlarged view of region PP of FIG. 2;

FIG. 5 is an enlarged view of region PP of FIG. 2;

FIG. 6 is an enlarged view of region PP of FIG. 2;

FIG. 7 is a cross-sectional view of the organic light-emitting display taken along line I-I′ of FIG. 1;

FIG. 8A, FIG. 8B, FIG. 8C, and FIG. 8D are cross-sectional views for describing a method of manufacturing an organic light-emitting display, according to an embodiment;

FIG. 9A and FIG. 9B are views of an example of a head-mounted display in which an organic light-emitting display according to an embodiment is implemented;

FIG. 10 is a view of an example of a display accommodation case of FIG. 9A and FIG. 9B; and

FIG. 11 is a view of another example of the display accommodation case of FIG. 9A and FIG. 9B.

### DETAILED DESCRIPTION

Hereinafter, embodiments will be described in detail by referring to the accompanying drawings. Like reference numerals refer to like elements, and their repetitive descriptions may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

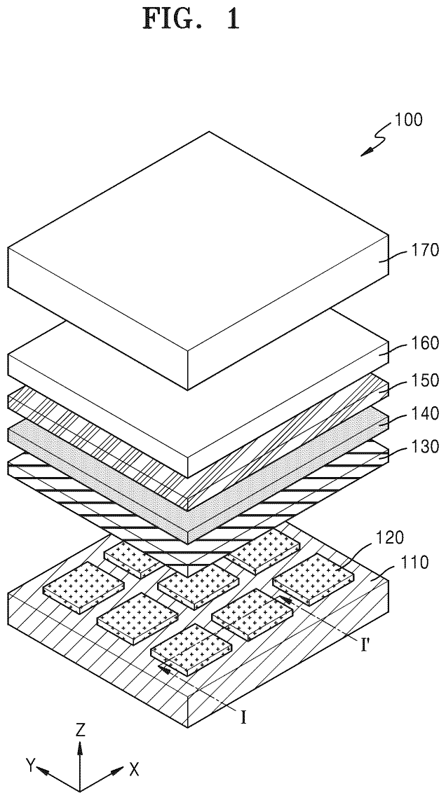

FIG. 1 is an exploded perspective view of an organic light-emitting display 100 according to an embodiment. In connection with FIG. 1, the organic light-emitting display 100 according to an embodiment is described as including an organic light-emitting diode on silicon (OLEDoS) formed by using a semiconductor process. However, the organic light-emitting display according to an embodiment is not limited thereto.

Referring to FIG. 1, the organic light-emitting display 100 according to an embodiment may include a substrate 110, a pixel electrode 120, a first organic emission layer 130, a second organic emission layer 140, a third organic emission layer 150, a common electrode 160, and an encapsulation layer 170. The substrate 110, the pixel electrode 120, the first organic emission layer 130, the second organic emission layer 140, the third organic emission layer 150, the common electrode 160, and the encapsulation layer 170 may be sequentially stacked.

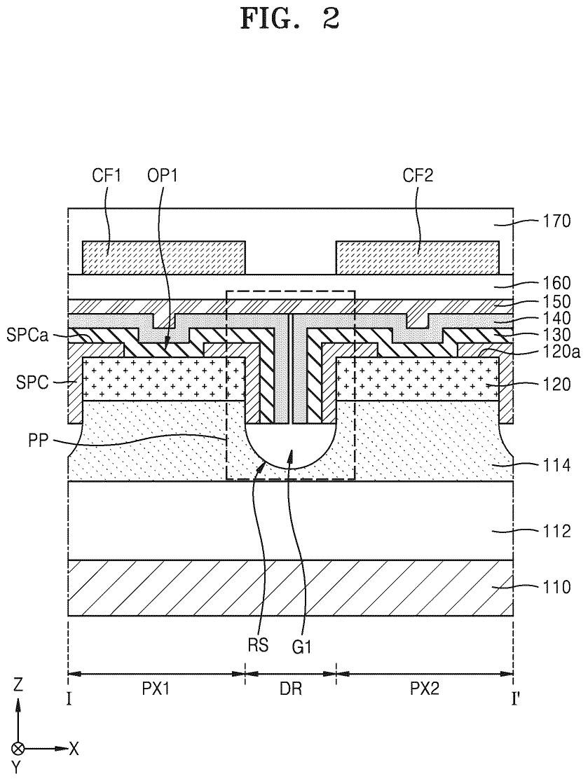

The substrate 110 may include a silicon wafer substrate. The silicon wafer substrate may be formed by using a semiconductor process. The substrate 110 in FIG. 1 may have a structure including the substrate 110, a circuit device layer 112, and an insulating layer 114 (see FIG. 2). The substrate 110 may include, for example, gate lines, data lines, and transistors. The gate lines and the data lines may be arranged to cross each other. The gate lines may be connected to a gate driver and may receive gate signals. The data lines may be connected to a data driver and may receive data voltages.

A region in which the pixel electrode 120 is disposed may be defined as a pixel. The pixel may be configured for emitting predetermined light. A plurality of pixel electrodes 120 may be disposed on the substrate 110. The plurality of pixel electrodes 120 may be arranged to have a predetermined distance from each other, and a plurality of pixels corresponding to the pixel electrodes 120 may have a predetermined distance from each other. N (N is a positive integer) transistors may be arranged in the pixel, and the N transistors may be configured to provide a predetermined voltage to the pixel electrode 120 according to the data voltage of the data line when the gate signal is input thereto from the gate line.

The first organic emission layer 130 may be disposed on the substrate 110 and the pixel electrode 120. The first organic emission layer 130 may cover the substrate 110 and the pixel electrode 120. The first organic emission layer 130 may be a common layer, commonly formed for the plurality of pixels. The second organic emission layer 140 may be disposed on the first organic emission layer 130. The second organic emission layer 140 may be a common layer, commonly formed for the plurality of pixels. The third organic emission layer 150 may be disposed on the second organic emission layer 140. The third organic emission layer 150 may be a common layer, commonly formed for the plurality of pixels.

The common electrode 160 may be disposed on the third organic emission layer 150. The common electrode 160 may also be a common layer, commonly formed for the pixels.

The encapsulation layer 170 may be disposed on the common electrode 160. The encapsulation layer 170 may prevent oxygen or water penetration into at least one of the first organic emission layer 130, the second organic emission layer 140, the third organic emission layer 150, or the common electrode 160.

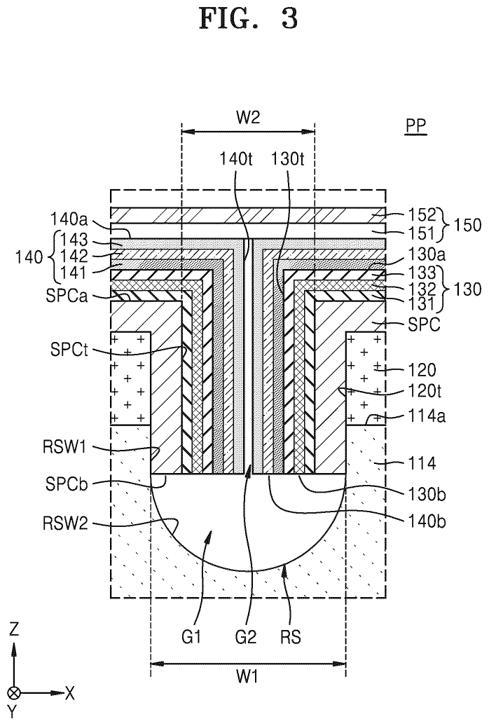

FIG. 2 is a cross-sectional view of the organic light-emitting display 100 taken along line I-I′ of FIG. 1. FIG. 3 is an enlarged view of region PP of FIG. 2. Hereinafter, the organic light-emitting display 100 according to one or more embodiments is described in detail with reference to FIG. 2 or/and FIG. 3.

Referring to FIG. 2, the substrate 110 may be provided. The substrate 110 may include a silicon-containing material. The substrate 110 may include silicon, monocrystalline silicon, polycrystalline silicon, amorphous silicon, silicon germanium, monocrystalline silicon germanium, polycrystalline silicon germanium, or carbon-doped silicon, or a combination thereof. The substrate 110 may include a signal layer or multiple layers. In a case that the substrate 110 is formed of multiple layers, different layers may be formed of the same or different materials. The substrate 110 may include other semiconductor materials, such as germanium. The substrate 110 may include a groups III/V compound semiconductor substrate, such as GaAs. The substrate 110 may include a silicon on insulator (SOI) substrate.

The substrate 110 may include a first pixel region PX1, a second pixel region PX2, and a division region DR. The first pixel region PX1 and the second pixel region PX2 may each indicate some of the plurality of pixels divided by the pixel electrodes 120. The first pixel region PX1 and the second pixel region PX2 may be adjacent to each other in a first horizontal direction X or a second horizontal direction Y. The division region DR may be arranged between the first pixel region PX1 and the second pixel region PX2. The first pixel region PX1 and the second pixel region PX2 may be spaced apart from each other in the first horizontal direction X or the second horizontal direction Y with the division region DR therebetween. The first pixel region PX1 and the second pixel region PX2 may be spaced apart from each other in a diagonal direction in the first horizontal direction X and the second horizontal direction Y with the division region DR therebetween.

In this specification, the first horizontal direction X may be defined as a direction parallel to a top surface of the substrate 110, the second horizontal direction Y may be defined as a direction crossing the first horizontal direction X and parallel with the top surface of the substrate 110, and a vertical direction Z may be defined as a direction perpendicular to the top surface of the substrate 110. For example, the vertical direction Z may be perpendicular to a plane formed by the first horizontal direction X and the second horizontal direction Y.

The circuit device layer 112 may be disposed on the substrate 110. A circuit device including various signal lines, thin-film transistors, capacitors, etc. may be disposed on the circuit device layer 112. The signal lines may include a gate line, a data line, a power line, and a reference line, and the thin-film transistors may include a switching thin-film transistor, a driving thin-film transistor, and a sensing thin-film transistor. The switching thin-film transistor may be switched according to a gate signal supplied to a gate line and may be configured to provide, to the driving thin-film transistor, a data voltage supplied from the data line. The driving thin-film transistor may be switched according to the data voltage supplied from the switching thin-film transistor and may be configured to generate a data current from power supplied from the power line and provide the data current to the pixel electrode 120. The sensing thin-film transistor may be configured to sense a threshold voltage deviation of the driving thin-film transistor. The threshold voltage deviation of the driving thin-film transistor may cause image quality deterioration. The sensing thin-film transistor may be configured to supply a current of the driving thin-film transistor to the reference line in response to a sensing control signal supplied from the gate line or an additional sensing line. The capacitor may be configured to maintain the data voltage supplied to the driving thin-film transistor during one frame. The capacitor may be connected to each of a gate terminal and a source terminal of the driving thin-film transistor.

The insulating layer 114 may be disposed on the circuit device layer 112. The insulating layer 114 may include an organic layer, such as acryl resins, epoxy resins, phenolic resins, polyamide resins, polyimide resins, or the like. Alternatively, the insulating layer 114 may include an inorganic layer, such as silicon nitride, silicon oxide, silicon oxynitride, aluminum oxide, titanium oxide, or the like. Although not shown, signal lines may be arranged in the insulating layer 114. Through the signal lines in the insulating layer 114 and the signal lines in the circuit device layer 112, the pixel electrode 120 and the driving thin-film transistor may be connected to each other.

The insulating layer 114 may include a recess RS in the division region DR of the substrate 110. Referring to FIG. 2 and FIG. 3 together, the insulating layer 114 may have a first inner side wall RSW1 and a second inner side wall RSW2 defining the recess RS. The first inner side wall RSW1 and the second inner side wall RSW2 may be defined as side walls exposed by the recess RS of the insulating layer 114. The first inner side wall RSW1 may define a middle portion of the recess RS and the second inner side wall RSW2 extending from the first inner side wall RSW1 may define a lower portion of the recess RS. The first inner side wall RSW1 and the second inner side wall RSW2 may be arranged in the recess RS. In a cross-sectional view, the first inner side wall RSW1 may have a straight-line shape. The first inner side wall RSW1 may downwardly extend from a top surface 114a of the insulating layer 114 toward the substrate 110. The first inner side wall RSW1 may downwardly extend in the vertical direction Z from a top surface 114a of the insulating layer 114. The first inner side wall RSW1 may be adjacent to the top surface 114a of the insulating layer 114. The second inner side wall RSW2 may be disposed below the top surface 114a of the insulating layer 114. The first inner side wall RSW1 may extend to the second inner side wall RSW2. The first inner side wall RSW1 may form an angle of about 75 degrees to about 105 degrees with respect to the first horizontal direction X. The first inner side wall RSW1 may have the straight-line shape in the cross-sectional view and the first inner side wall RSW1 may form the angle of about 75 degrees to about 105 degrees with respect to the first horizontal direction X. Such an arrangement of the first inner side wall RSW1 may be formed by a dry etch process.

The second inner side wall RSW2 may be a portion of a side wall of the insulating layer 114 that extends from the first inner side wall RSW1. In a cross-sectional view, the second inner side wall RSW2 may have a curved shape, for example, the second inner side wall RSW2 may have an oval shape or a round shape. The second inner side wall RSW2 may have the curved-shaped cross-section. Such an arrangement of the second inner side wall RSW2 may be formed by a wet etch process. The second inner side wall RSW2 may be a portion of a side wall of the insulating layer 114 that is formed by the recess RS, the portion excluding the first inner side wall RSW1. Compared with the first inner side wall RSW1, the second inner side wall RSW2 may be below the top surface 114a of the insulating layer 114 in the vertical direction Z.

A space defined by the second inner side wall RSW2 of the insulating layer 114 may be a first cavity G1. The first cavity G1 may indicate a space in the recess RS, which is not occupied by other elements of the organic light-emitting display 100. The first cavity G1 may be an air gap. A width of the first cavity G1 in the first horizontal direction X may be a first width W1. The first width W1 may be a maximum width of the portion of the recess RS that is defined by the second inner side wall RSW2. In other words, the first width W1 may be a distance between a portion of the second inner side wall RSW2 at first inner side wall RSW1 and arranged at a first side of the recess RS and a portion of the second inner side wall RSW2 at first inner side wall RSW1 and arranged at a second side of the recess RS. For example, the second inner side wall RSW2 may have the curved-shaped cross-section having a concave inner surface, wherein a depth of the recess RS having a concave shape along the second inner side wall RSW2 may increase toward a middle portion thereof.

Referring to FIG. 2 again, the pixel electrode 120 may be disposed on the insulating layer 114. The pixel electrode 120 may be an anode. The pixel electrode 120 may be provided in a multiple. The pixel electrodes 120 may be include a first pixel electrode disposed in the first pixel region PX1 and a second pixel electrode disposed in the second pixel region PX2 of the substrate 110. A pixel electrode 120 may not be arranged in the division region DR of the substrate 110. The pixel electrode 120 may include a single layer or multiple layers. Although not shown, according to the design of the organic light-emitting display 100, the pixel electrode 120 may further include a reflection electrode or/and a buffer electrode, in addition to the anode. The pixel electrode 120 may include a transparent conductive material (TCO), such as ITO and IZO.

Referring to FIG. 2 and FIG. 3 again, a spacer SPC may be disposed on the pixel electrode 120. The spacer SPC may be disposed on a side wall 120t of the pixel electrode 120. The side wall 120t of the pixel electrode 120 may define an upper portion of the recess RS. The first inner side wall RSW1 may extend from the side wall 120t of the pixel electrode 120. The spacer SPC may extend onto a top surface 120a of the pixel electrode 120. The spacer SPC may extend onto the first inner side wall RSW1 of the insulating layer 114. The spacer SPC may be disposed on the side wall 120t of the pixel electrode 120 and may be disposed on at least a portion of the top surface 120a of the pixel electrode 120. The spacer SPC may completely cover the side wall 120t of the pixel electrode 120. The spacer SPC may be disposed on an edge portion of the top surface 120a of the pixel electrode 120. The spacer SPC may be disposed on the first inner side wall RSW1. The spacer SPC may include a first opening OP1 exposing at least a portion of the top surface 120a of the pixel electrode 120. A vertical level of a bottommost surface SPCb of the spacer SPC may be disposed lower than a vertical level of the top surface 114a of the insulating layer 114. The spacer SPC may include a material having an etch selectivity that is substantially different than that of the insulating layer 114. The spacer SPC may include silicon nitride, silicon oxide, silicon oxynitride, or a combination thereof.

The first organic emission layer 130 may be disposed on the pixel electrode 120 and the spacer SPC. The first organic emission layer 130 may cover a side wall SPCt and a top surface SPCa of the spacer SPC. The side wall SPCt of the spacer SPC may indicate a portion of a surface of the spacer SPC that extends in the vertical direction Z in the division region DR. A height of the side wall 120t of the pixel electrode 120 may be at least half of a height of the side wall SPCt of the spacer SPC. The height of the side wall SPCt of the spacer SPC may cover more than half a height of the first inner side wall RSW1 of the recess RS in the first horizontal direction X. The height of the side wall SPCt of the spacer SPC may cover an entirety of the height of the first inner side wall RSW1 of the recess RS in the first horizontal direction X. The first organic emission layer 130 may cover the top surface 120a of the pixel electrode 120 that is exposed to the first opening OP1 of the spacer SPC. A vertical level of a bottommost surface 130b of the first organic emission layer 130 may be substantially the same as the vertical level of the bottommost surface SPCb of the spacer SPC.

A distance between the spacer SPC in the first pixel region PX1 and the spacer SPC in the second pixel region PX2 may be a second width W2. The second width W2 may be a minimum distance between both side walls SPCt of the spacer SPC that face each other in the first horizontal direction X, in the division region DR. The second width W2 may be less than the first width W1. In other words, the first width W1 may be greater than the second width W2.

In each of the first pixel region PX1 and the second pixel region PX2, the first organic emission layer 130 may continually extend on the pixel electrode 120 and the spacer SPC. The first organic emission layer 130 may be disconnected in the division region DR. For example, the first organic emission layer 130 in the first pixel region PX1 and the first organic emission layer 130 in the second pixel region PX2 may be electrically disconnected from each other. The first organic emission layer 130 in the first pixel region PX1 and the first organic emission layer 130 in the second pixel region PX2 may be spaced apart from each other in the first horizontal direction X.

The first organic emission layer 130 may include a first stack 131, a second stack 132, and a first charge generation layer 133 that are sequentially stacked. The first stack 131 may be disposed on the spacer SPC and may be disposed on the top surface 120a of the pixel electrode 120 that is exposed to the first opening OP1. The first stack 131 may include a first hole injection layer and a first hole transport layer that are sequentially stacked. The first stack 131 may further include a first emission layer on the first hole transport layer. The second stack 132 may be disposed on the first stack 131. The second stack 132 may include a first electron transport layer and a first electron injection layer that are sequentially stacked. The first charge generation layer 133 may be disposed on the second stack 132. The first charge generation layer 133 may include an N-type charge generation layer and a P-type charge generation layer that are sequentially stacked. The first organic emission layer 130 may be disconnected in the division region DR, and the first charge generation layer 133 included in the first organic emission layer 130 may also be disconnected in the division region DR.

The second organic emission layer 140 may be disposed on the first organic emission layer 130. The second organic emission layer 140 may be disposed on a side wall 130t of the first organic emission layer 130 and may be disposed on a top surface 130a of the first organic emission layer 130. A vertical level of a bottommost surface 140b of the second organic emission layer 140 may be substantially equal to the vertical level of the bottommost surface 130b of the first organic emission layer 130. In the first pixel region PX1 and the second pixel region PX2, the second organic emission layer 140 may continually extend on the first organic emission layer 130. However, the second organic emission layer 140 may be disconnected in the division region DR, and the second organic emission layer 140 in the first pixel region PX1 and the second organic emission layer 140 in the second pixel region PX2 may be electrically disconnected from each other. A second cavity G2 may be disposed between the second organic emission layer 140 in the first pixel region PX1 and the second organic emission layer 140 in the second pixel region PX2. The second organic emission layer 140 in the first pixel region PX1 and the second organic emission layer 140 in the second pixel region PX2 may be spaced apart from each other with the second cavity G2 therebetween. The second cavity G2 may be connected to the first cavity G1. The second cavity G2 may include an air gap.

The second organic emission layer 140 may include a third stack 141, a fourth stack 142, and a second charge generation layer 143 that are sequentially stacked. The third stack 141 may be disposed on the first organic emission layer 130. The third stack 141 may include a second hole injection layer and a second hole transport layer that are sequentially stacked. The third stack 141 may further include a second emission layer disposed on the second hole transport layer. The fourth stack 142 may be disposed on the third stack 141. The fourth stack 142 may include a second electron transport layer and a second electron injection layer that are sequentially stacked. The second charge generation layer 143 may be disposed on the fourth stack 142. The second charge generation layer 143 may include an N-type charge generation layer and a P-type charge generation layer that are sequentially stacked. The second organic emission layer 140 may be disconnected in the division region DR, and the second charge generation layer 143 may also be disconnected in the division region DR.

The third organic emission layer 150 may be disposed on the second organic emission layer 140. The third organic emission layer 150 may be disposed on a top surface 140a of the second organic emission layer 140. The third organic emission layer 150 may cover the second cavity G2. A side surface 140t of the second organic emission layer 140 may be exposed to the second cavity G2. For example, the third organic emission layer 150 may not be formed on the side surface 140t of the second organic emission layer 140 in the second cavity G2. The third organic emission layer 150 may extend in the first horizontal direction X and the second horizontal direction Y. The third organic emission layer 150 may continually extend from the first pixel region PX1 to the second pixel region PX2.

The third organic emission layer 150 may include a fifth stack 151 and a sixth stack 152 that are sequentially stacked. The fifth stack 151 may include a third hole injection layer and a third hole transport layer that are sequentially stacked. The fifth stack 151 may further include a third emission layer disposed on the third hole transport layer. The sixth stack 152 may be disposed on the fifth stack 151. The sixth stack 152 may include a third electron transport layer and a third electron injection layer that are sequentially stacked.

The first organic emission layer 130, the second organic emission layer 140, and the third organic emission layer 150 may generate different color light from one another. For example, the first organic emission layer 130, the second organic emission layer 140, and the third organic emission layer 150 may generate light of any one color from among red, green, or blue. To generate white light, the first charge generation layer 133 and the second charge generation layer 143 may simultaneously inject an electron and a hole to the first emission layer of the first organic emission layer 130, the second emission layer of the second organic emission layer 140, and the third emission layer of the third organic emission layer 150. When the first charge generation layer 133 and the second charge generation layer 143 continually extend from the first pixel region PX1 to the second pixel region PX2, noise may be generated in an adjacent pixel region during emission in first pixel region. Noise may be reduced or eliminated where each of the first charge generation layer 133 and the second charge generation layer 143 have been disconnected in the division region DR.

The common electrode 160 may be disposed on the third organic emission layer 150. The common electrode 160 may be a cathode. The common electrode 160 may extend in the first horizontal direction X and the second horizontal direction Y. The common electrode 160 may continually extend from the first pixel region PX1 to the second pixel region PX2. The common electrode 160 may also be disposed in the division region DR. The common electrode 160 may be disposed on a top surface of the third organic emission layer 150 in the division region DR.

A first color filter CF1 and a second color filter CF2 may be disposed on the common electrode 160. The first color filter CF1 may be arranged in the first pixel region PX1 and the second color filter CF2 may be arranged in the second pixel region PX2.

The encapsulation layer 170 may be disposed on the first color filter CF1 and the second color filter CF2. The encapsulation layer 170 may encapsulate the first color filter CF1 and the second color filter CF2. The first color filter CF1 and the second color filter CF2 may exposed the common electrode 160 in the division region DR. The encapsulation layer 170 may be disposed on a top surface of the common electrode 160 in the division region DR. The encapsulation layer 170 may reduce or prevent the penetration of oxygen or water into an underlying layer. For example, the encapsulation layer 170 may reduce or prevent the penetration of oxygen or water into the pixel electrode 120, the first organic emission layer 130, the second organic emission layers 140, the third organic emission layer 150, the common electrode 160, the first color filter CF1, and the second color filter CF2. The encapsulation layer 170 may include at least one inorganic layer and at least one organic layer.

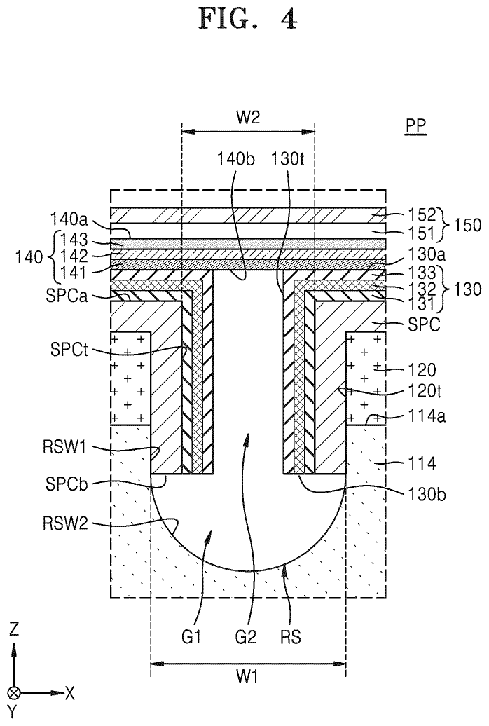

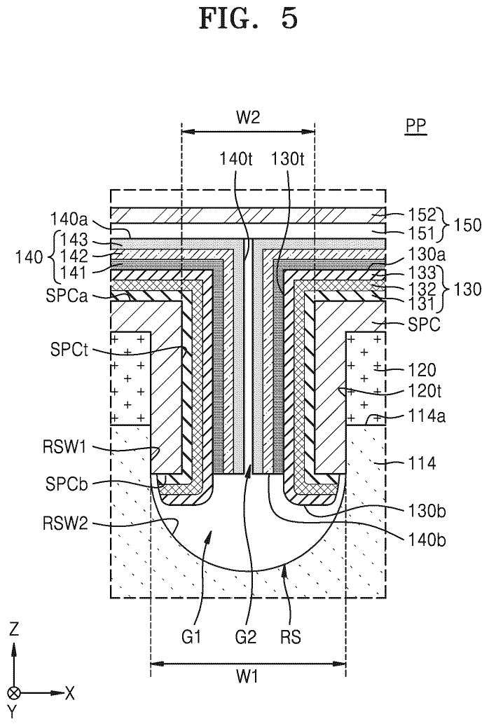

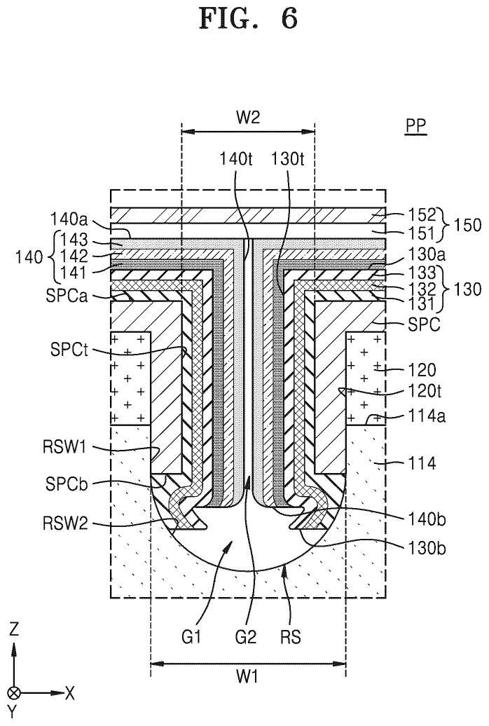

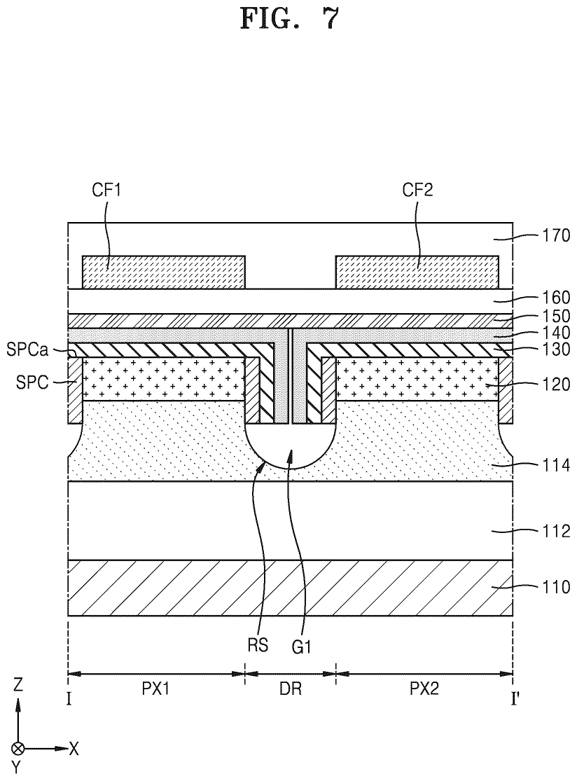

FIG. 4 is an enlarged view of region PP of FIG. 2. FIG. 5 is an enlarged view of region PP of FIG. 2. FIG. 6 is an enlarged view of region PP of FIG. 2. FIG. 7 is a cross-sectional view of the organic light-emitting display taken along line I-I′ of FIG. 1. Hereinafter, certain aspects of FIGS. 4-7 may be the same as those described with reference to FIG. 2 and FIG. 3 and redundant descriptions thereof may be omitted, while differences may be described in detail.

Referring to FIG. 4, the second organic emission layer 140 may continually extend from the first pixel region PX1 to the second pixel region PX2. The second organic emission layer 140 may be disposed on the top surface 130a of the first organic emission layer 130. At least a portion of the side wall 130t of the first organic emission layer 130 may be exposed on the second organic emission layer 140. The second organic emission layer 140 may continually extend in the division region DR and may not be disconnected in the division region DR. In the division region DR, the vertical level of the bottom surface 140b of the second organic emission layer 140 may be greater than the vertical level of the bottom surface 130b of the first organic emission layer 130. In the division region DR, the vertical level of the bottom surface 140b of the second organic emission layer 140 may be less than, or substantially the same as the vertical level of the top surface 130a of the first organic emission layer 130.

Referring to FIG. 5, the first organic emission layer 130 may further extend to the bottommost surface SPCb of the spacer SPC. For example, the first organic emission layer 130 may be disposed on the bottommost surface SPCb of the spacer SPC. The first organic emission layer 130 may cover at least a portion of the bottommost surface SPCb of the spacer SPC. The vertical level of the bottom surface 130b of the first organic emission layer 130 may be less than the vertical level of the bottommost surface SPCb of the spacer SPC. The first organic emission layer 130 may be spaced apart from the second inner side wall RSW2.

Although not shown, the second organic emission layer 140 may further extend to cover at least a portion of a surface of the first organic emission layer 130 extended to the bottommost surface SPCb of the spacer SPC. Here, the vertical level of the bottom surface 140b of the second organic emission layer 140 may be less than or greater than, or may be substantially the same as the vertical level of the bottom surface 130b of the first organic emission layer 130.

Referring to FIG. 6, the first organic emission layer 130 may further extend to the bottommost surface SPCb of the spacer SPC. The first organic emission layer 130 may entirely cover the bottommost surface SPCb of the spacer SPC. The vertical level of the bottom surface 130b of the first organic emission layer 130 may be less than the vertical level of the bottommost surface SPCb of the spacer SPC. The first organic emission layer 130 may further extend to cover at least a portion of the second inner side wall RSW2. For example, the first organic emission layer 130 may be disposed on at least a portion of the second inner side wall RSW2. At least a portion of the second inner side wall RSW2 may be exposed on the first organic emission layer 130.

The second organic emission layer 140 may further extend to cover a surface of a further extending portion of the first organic emission layer 130. Here, the vertical level of the bottom surface 140b of the second organic emission layer 140 may be less than or greater than or may be substantially the same as the vertical level of the bottom surface 130b of the first organic emission layer 130.

Referring to FIG. 7, the spacer SPC may be disposed on the side wall (120t of FIG. 3) and the first inner side wall (RSW1 of FIG. 3) of the pixel electrode 120. The top surface 120a of the pixel electrode 120 may be exposed on the spacer SPC. For example, an entirety of the top surface 120a of the pixel electrode 120 may be exposed on the spacer SPC. Accordingly, an area in which the first organic emission layer 130 is in contact with the pixel electrode 120 may increase.

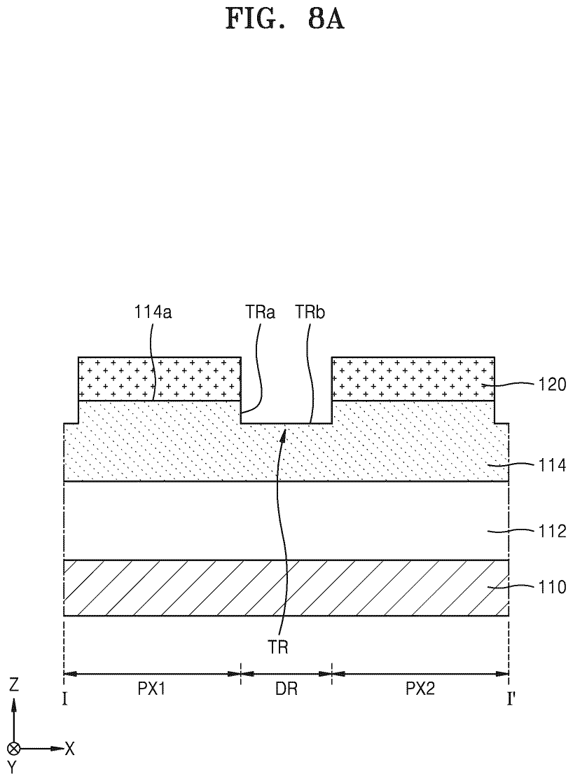

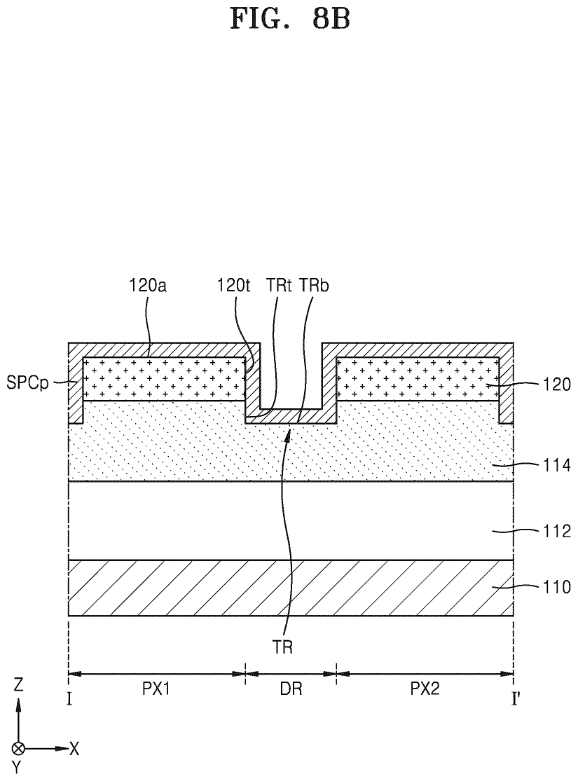

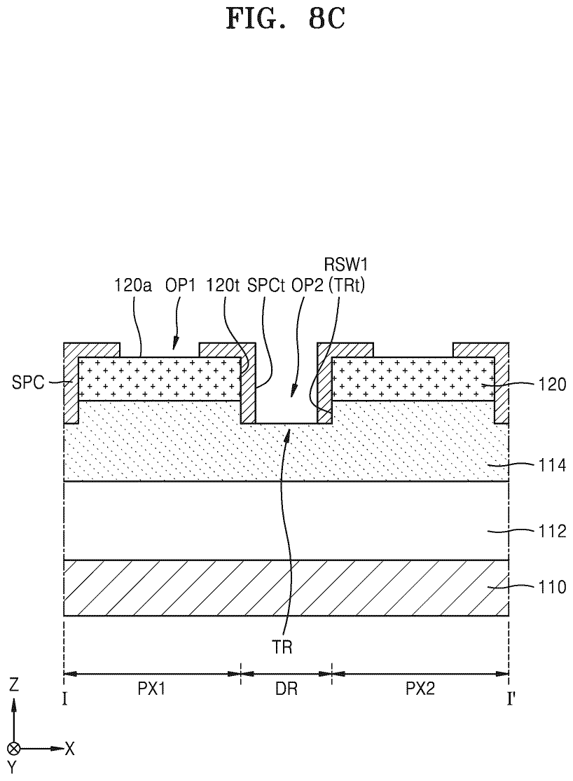

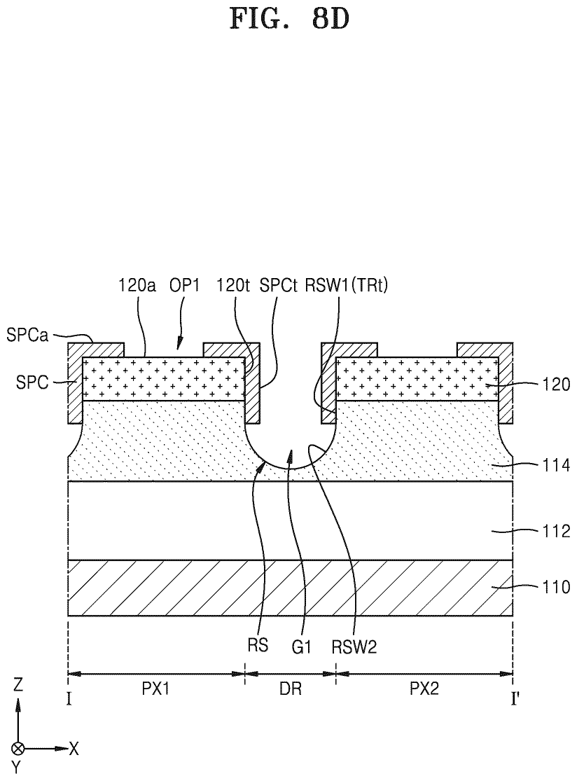

FIG. 8A, FIG. 8B, FIG. 8C, and FIG. 8D are cross-sectional views for describing a method of manufacturing an organic light-emitting display, according to an embodiment. Hereinafter, a method of manufacturing the organic light-emitting display is described with reference to FIGS. 8A to 8D.

Referring to FIG. 8A, the circuit device layer 112 may be disposed on the substrate 110 including the first pixel region RX1, the second pixel region PX2, and the division region DR. The insulating layer 114 may be disposed on the circuit device layer 112. The first pixel region PX1 and the second pixel region PX2 may be spaced apart from each other in the first horizontal direction X with the division region DR disposed therebetween. On the insulating layer 114, the pixel electrode 120 may be formed patterning a material in the first pixel region PX1 and the second pixel region PX2. The insulating layer 114 may include an organic layer such as acryl resins, epoxy resins, phenol resins, polyamide resins, polyimide resins, etc. Alternatively, the insulating layer 114 may include an inorganic layer, such as silicon nitride, silicon oxide, silicon oxynitride, aluminum oxide, or titanium oxide.

A dry etch process may be performed by using the pixel electrode 120 as an etch mask to form a trench TR in the insulating layer 114. Due to the characteristics of the dry etch process, a side wall TRt of the trench TR may form an angle of about 75 degrees to about 105 degrees with respect to the first horizontal direction X. A vertical level of a bottom surface TRb of the trench TR may be lower than the vertical level of the top surface 114a of the insulating layer 114.

Referring to FIG. 8B, the spacer layer SPCa disposed on the pixel electrode 120 may be formed. The spacer layer SPCa may be disposed on the top surface 120a and the side wall 120t of the pixel electrode 120 and the side wall TRt and the bottom surface TRb of the trench TR. The spacer layer SPCa may include a material having an etch selectivity different than the insulating layer 114. the spacer layer SPCa may include, for example, silicon oxide, silicon nitride, silicon oxynitride, or a combination thereof. Methods of forming the spacer layer SPCa may include physical vapor deposition (PVD), chemical vapor deposition (CVD), low pressure CVD (LPCVD), plasma-enhanced CVD (PECVD), atomic layer deposition (ALD), or a combination thereof.

Referring to FIG. 8C, the spacer SPC may be formed. The forming of the spacer SPC may include forming a photomask pattern on the spacer layer SPCa by performing an exposure and development process, performing a dry etch process by using the photomask pattern as an etch mask, and performing ashing and stripping. The spacer SPC may include the first opening OP1 exposing at least a portion of the top surface 120a of the first pixel electrode in the first pixel region PX1 and the second pixel electrode in the second pixel region PX2, and the second opening OP2 exposing the bottom surface TRb of the trench TR in the division region DR. The spacer SPC may be disposed on at least a portion of the top surface 120a of the pixel electrode 120 and the side wall 120t of the pixel electrode 120. The spacer SPC may cover the side wall TRT of the trench TR.

Referring to FIG. 8D, a wet etch process may be performed on the insulating layer 114 through the second opening OP2. Due to the wet etch process, the recess RS may be generated in the insulating layer 114. The insulating layer 114 may have the second inner side wall RSW2 due to the recess RS. The recess RS may be connected to the trench TR. For convenience of explanation, the recess RS and the trench TR formed by the wet etch process in FIG. 8D are collectively referred to as the recess RS. The side wall TRt of the trench TR may be referred to as the first inner side wall RSW1. The first inner side wall RSW1 may be formed through the dry etch process, and the first inner side wall RWS1 may have a straight-shaped cross-section. The side wall 120t of the pixel electrode 120 and the first inner side wall RWS1 may have a straight-shaped cross-section. The second inner side wall RSW2 may be formed through the wet etch process, and the second inner side wall RSW2 may have a curved-shaped cross-section. A space surrounded by the second inner side wall RSW2 may be defined as the first cavity G1.

Referring to FIG. 2 and FIG. 3 again, the first organic emission layer 130 may be disposed on the pixel electrode 120 and the spacer SPC. The first organic emission layer 130 may be disposed on the top surface SPCa and the side wall SPCt of the spacer SPC. The first organic emission layer 130 may be disposed on the top surface 120a of the pixel electrode 120 that is exposed to the first opening OP1. The first organic emission layer 130 may continually extend in each of the first pixel region PX1 and the second pixel region PX2. The first organic emission layer 130 may be disconnected in the division region DR. That is, the first organic emission layer 130 in the first pixel region PX1 and the first organic emission layer 130 in the second pixel region PX2 may be spaced apart from each other. The first organic emission layer 130 may include the first stack 131, the second stack 132, and the first charge generation layer 133 that are sequentially stacked.

Methods of forming the first organic emission layer 130 may include, for example, PVD, CVD, LPCVD, PECVD, ALD, or a combination thereof.

The second organic emission layer 140 may be disposed on the first organic emission layer 130. The second organic emission layer 140 may be disposed on the top surface 130a and the side wall 130t of the first organic emission layer 130. The second organic emission layer 140 may continually extend in each of the first pixel region PX1 and the second pixel region PX2. The second organic emission layer 140 may be disconnected in the division region DR. The second organic emission layer 140 in the first pixel region PX1 and the second organic emission layer 140 in the second pixel region PX2 may be electrically disconnected from each other. The second cavity G2 may be disposed between the second organic emission layer 140 in the first pixel region PX1 and the second organic emission layer 140 in the second pixel region PX2. The second organic emission layer 140 in the first pixel region PX1 and the second organic emission layer 140 in the second pixel region PX2 may be spaced apart from each other with the second cavity G2 disposed therebetween. The second cavity G2 may be connected to the first cavity G1. The second cavity G2 may include an air gap. For example, a disconnection between the second organic emission layer 140 in the first pixel region PX1 and the second organic emission layer 140 in the second pixel region PX2 may be embodied by the air gap provided by the second cavity G2. The second organic emission layer 140 may include the third stack 141, the fourth stack 142, and the second charge generation layer 143 that are sequentially stacked.

Methods of forming the second organic emission layer 140 may include, for example, PVD, CVD, LPCVD, PECVD, ALD, or a combination thereof.

The third organic emission layer 150 may be disposed on the second organic emission layer 140. The third organic emission layer 150 may continually extend from the first pixel region PX1 to the second pixel region PX2 in the first horizontal direction X. The third organic emission layer 150 may be disposed over the second cavity G2. For example, the third organic emission layer 150 may bridge the second cavity G2. The third organic emission layer 150 may include the fifth stack 151 and the sixth stack 152 that are sequentially stacked. Methods of forming the third organic emission layer 150 may include, for example, PVD, CVD, LPCVD, PECVD, ALD, or a combination thereof.

The common electrode 160 may be disposed on the third organic emission layer 150. The common electrode 160 may continually extend from the first pixel region PX1 to the second pixel region PX2 in the first horizontal direction X.

The first color filter CF1 and the second color filter CF2 may be formed on the common electrode 160. The encapsulation layer 170 may be disposed on the first color filter CF1 and the second color filter CF2. Thus, the organic light-emitting display 100 may be manufactured.

The first organic emission layer 130 and the second organic emission layer 140 may be disconnected from each other in the division region DR. The first charge generation layer 133 and the second charge generation layer 143 may be disconnected as described herein. For example, the first organic emission layer 130 and the second organic emission layer 140 may be disconnected from each other and the first charge generation layer 133 included in the first organic emission layer 130 and the second charge generation layer 143 included in the second organic emission layer 140 may be disconnected from each. The common electrode 160 may continually extend from the first pixel region PX1 to the second pixel region PX2 and the common electrode 160 may be spaced apart from the circuit device layer 112 in the vertical direction Z, compared with the pixel electrode 120 and the first organic emission layer 130, the second organic emission layers 140, and the third organic emission layer 150. The common electrode 160 may not be disconnected, and integration of metal wiring may be implemented without difficulty.

When the insulating layer 114 includes only the trench TR described with reference to FIG. 8A and does not include the recess RS described with reference to FIG. 8D, the disconnection with respect to each of the first organic emission layer 130 and the second organic emission layer 140 and the common electrode 160 may be changed according to a width and a depth of the trench TR. For example, a thicknesses of the first organic emission layer 130, the second organic emission layer 140, and the common electrode 160 may vary according to the design of the organic light-emitting display 100. For example, when the width and the depth of the trench TR increase when the thicknesses of the first organic emission layer 130, the second organic emission layer 140, and the common electrode 160 are small, the first organic emission layer 130 and the second organic emission layer 140 may not be sufficiently deposited, and the common electrode 160 may be disconnected. When the width and the depth of the trench TR decrease when the thicknesses of the first organic emission layer 130, the second organic emission layer 140, and the common electrode 160 are large, each of the first organic emission layer 130 and the second organic emission layer 140 may not be disconnected. When the insulating layer 114 includes only the trench TR described with reference to FIG. 8A and does not include the recess RS described with reference to FIG. 8D, the width and the depth of the trench TR may need to be differently adjusted for every manufacture to ensure that each of the first organic emission layer 130 and the second organic emission layer 140 may be disconnected and the common electrode 160 may be continually extended. An adjustment of the width and the depth of the trench TR may lead to the addition of a process of measuring the width and the depth of the trench TR, and the number of process steps may be increased, which may result in increased manufacturing time and expenses.

According to the inventive concept, the insulating layer 114 may include the recess RS, and the recess RS may have the first inner side wall RSW1 having a substantially straight shape and the second inner side wall RSW2 extending from the first inner side wall RSW1. A width of a portion of the recess RS that is defined by the second inner side wall RSW2 may be a first width W1, and a distance from the spacer SPC in the first pixel region PX1 and the spacer SPC in the second pixel region PX2 may be a second width W2. The first width W1 may be greater than the second width W2. Thus, even when the width and the depth of the trench TR in FIG. 8A are constant, disconnection of each of the first organic emission layer 130 and the second organic emission layer 140 may be substantially ensured. When thicknesses of the first organic emission layer 130 and the second organic emission layer 140 are small, a thickness of the spacer SPC may be increased to induce a disconnection of each of the first organic emission layer 130 and the second organic emission layer 140. When the thicknesses of the first organic emission layer 130 and the second organic emission layer 140 are large, the first organic emission layer 130 and the second organic emission layer 140 may extend to the second inner side wall RSW2, and the degree of deposition of the first organic emission layer 130 and the second organic emission layer 140 on the inner side wall SPCt of the spacer SPC may be relatively decreased. Based on this structure, even when the thicknesses of the first organic emission layer 130 and the second organic emission layer 140 are large, disconnection of each of the first organic emission layer 130 and the second organic emission layer 140 may be substantially ensured. Therefore, noise which may occur in a case that each of the first organic emission layer 130 and the second organic emission layer 140 are not disconnected may be resolved. Based on these aspects, the reliability of the organic light-emitting display 100 may be improved.

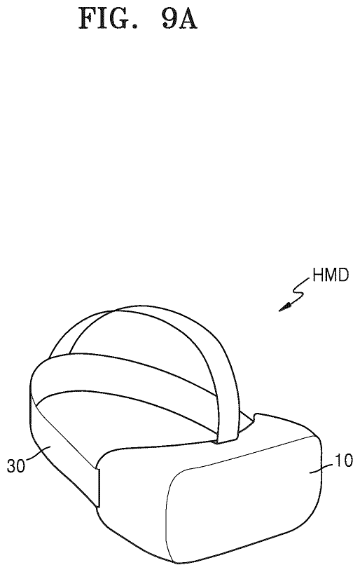

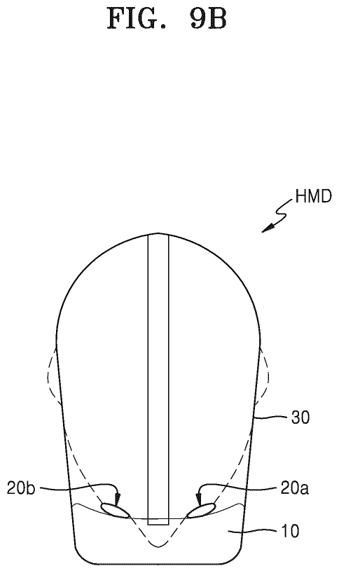

FIG. 9A and FIG. 9B are views of an example of a head-mounted display HMD in which an organic light-emitting display according to an embodiment may be implemented.

Referring to FIG. 9A and FIG. 9B, the head-mounted display HMD in which the organic light-emitting display (100 of FIG. 2) according to an embodiment may be implemented may include a display accommodation case 10, a left-eye lens 20a, a right-eye lens 20b, and a head-mounted band 30.

The display accommodation case 10 may accommodate a display and may provide an image(s) of the display to the left-eye lens 20a and the right-eye lens 20b. The display may be the organic light-emitting display (100 of FIG. 2) according to an embodiment. The organic light-emitting display (100 of FIG. 2) according to an embodiment is described herein in detail with reference to the drawings.

The display accommodation case 10 may be designed to provide the same image to the left-eye lens 20a and the right-eye lens 20b. Alternatively, the display accommodation case 10 may be designed such that a left-eye image is displayed on the left-eye lens 20a and a right-eye image is displayed on the right-eye lens 20b. The structures of FIG. 9A and FIG. 9B may be implemented in a virtual reality (VR) device, for example.

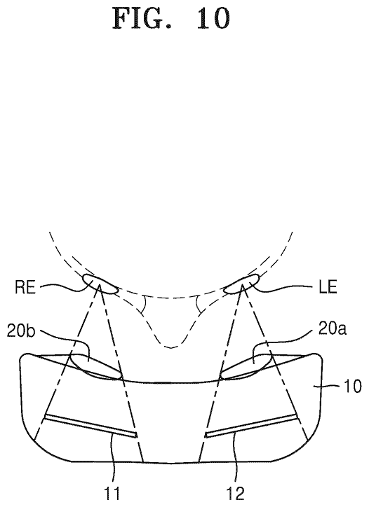

FIG. 10 is a view of an example of the display accommodation case 10 of FIGS. 9A and 9B.

FIG. 10 is a cross-sectional view of the display accommodation case 10 downwardly viewed. An organic light-emitting display 11 for a left eye may display a left-eye image, and an organic light-emitting display 12 for a right eye may display a right-eye image. Thus, the left-eye image displayed by the organic light-emitting display 11 for the left eye may be shown to a left eye LE of a user through the left-eye lens 20a, and the right-eye image displayed by the organic light-emitting display 12 for the right eye may be shown to a right eye RE of the user through the right-eye lens 20b.

A magnifying lens may be disposed between the left-eye lens 20a and the organic light-emitting display 11 for the left eye and between the right-eye lens 20b and the organic light-emitting display 12 for the right eye in FIG. 10. In this case, due to the magnifying lens, images displayed by the organic light-emitting display 11 for the left eye and the organic light-emitting display 12 for the right eye may be magnified and shown to the user. The structure of FIG. 10 may be implemented in an augmented reality (AR) device, for example.

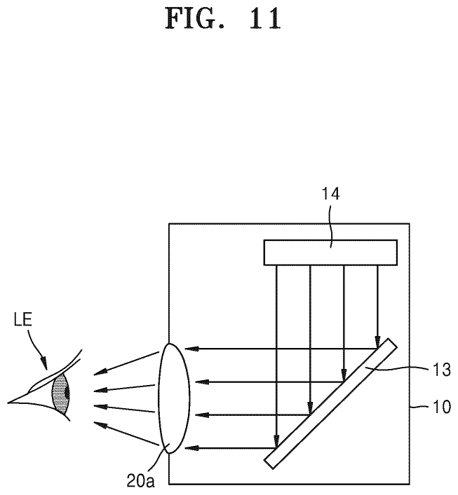

FIG. 11 is a view of another example of the display accommodation case 10 of FIG. 9A and FIG. 9B.

FIG. 11 is a cross-sectional view of the display accommodation case 10 laterally viewed. An organic light-emitting display 14 may display an image in a direction of a mirror reflection plate 13, and the mirror reflection plate 13 may totally reflect the image of the organic light-emitting display 14 in directions of the left-eye lens 20a and the right-eye lens 20b. The image displayed by the organic light-emitting display 14 may be provided to the left-eye lens 20a and the right-eye lens 20b. FIG. 11 illustrates only the left-eye lens 20a and the left eye LE of the user for convenience of explanation. As illustrated in FIG. 11, when the mirror reflection plate 13 is a half-mirror, the display accommodation case 10 may be thinly formed.

A magnifying lens may be disposed between the left-eye lens 20a and the mirror reflection plate 13 and between the right-eye lens 20b and the mirror reflection plate 13 in FIG. 11. In this case, due to the magnifying lens, images displayed by the organic light-emitting display 11 for the left eye and the organic light-emitting display 12 for the right eye may be magnified and shown to the user.

The head-mounted band 30 may be fixed to the display accommodation case 10. It is illustrated that the head-mounted band 30 may be formed to surround a top surface and both side surfaces of the head of a user, but the head-mounted band 30 not limited thereto. The head-mounted band 30 may be used to fix the head mounted display HMD to the head of the user and may be formed as a glasses frame or a helmet.

While an inventive concept has been particularly shown and described with reference to example embodiments thereof, it will be understood that various changes in form and details may be made therein without departing from the spirit and scope of the following claims.

What is claimed is:

1. An organic light-emitting display comprising:
a substrate including a first pixel region, a second pixel region, and a division region disposed between the first pixel region and the second pixel region;
an insulating layer disposed on the substrate and including a recess disposed in the division region, the insulating layer including a first inner side wall defining a first portion of the recess and a second inner side wall extending from the first inner side wall, defining a second portion of the recess, and having a curved shape;
a plurality of pixel electrodes disposed on the insulating layer, and including a first pixel electrode in the first pixel region and a second pixel electrode in the second pixel region;
a spacer disposed on a side wall of each of the pixel electrodes and the first inner side wall of the insulating layer; and
a first organic emission layer disposed on the spacer,
wherein the spacer includes a material having an etch selectivity different than an etch selectivity of the insulating layer.

2. The organic light-emitting display of claim 1, wherein the first organic emission layer comprises:
a first stack;
a second stack disposed on the first stack; and
a first charge generation layer disposed on the second stack,
wherein in the division region, the first organic emission layer is disposed on at least a portion of a side wall of the spacer.

3. The organic light-emitting display of claim 2, wherein the first organic emission layer extends to a bottommost surface of the spacer.

4. The organic light-emitting display of claim 2, wherein the first organic emission layer is disposed on at least a portion of the second inner side wall.

5. The organic light-emitting display of claim 1, wherein the first organic emission layer includes a first portion disposed in the first pixel region and a second portion disposed in the second pixel region and disconnected in the division region from the first portion of the first organic emission layer.

6. The organic light-emitting display of claim 5, further comprising a common electrode disposed on the first organic emission layer,
wherein the common electrode continually extends from the first pixel region to the second pixel region, through the division region.

7. The organic light-emitting display of claim 1, wherein the spacer is disposed on a top surface of each of the pixel electrodes, the side wall of each of the pixel electrodes, and the first inner side wall of the insulating layer having a straight-line shape.

8. The organic light-emitting display of claim 1, further comprising:
a second organic emission layer disposed on the first organic emission layer; and
a third organic emission layer disposed on the second organic emission layer,
wherein the second organic emission layer includes a third stack, a fourth stack, and a second charge generation layer that are sequentially stacked, and
the third organic emission layer includes a fifth stack and a sixth stack that are sequentially stacked.

9. The organic light-emitting display of claim 8, wherein each of the first organic emission layer and the second organic emission layer is disposed in the first pixel region and the second pixel region and is disconnected in the division region.

10. The organic light-emitting display of claim 9, wherein the third organic emission layer continually extends from the first pixel region to the second pixel region, through the division region.

11. The organic light-emitting display of claim 8, wherein the first organic emission layer is disposed in the first pixel region and the second pixel region and is disconnected in the division region, and
the second organic emission layer continually extends from the first pixel region to the second pixel region, through the division region.

12. The organic light-emitting display of claim 1, wherein the first organic emission layer is in contact with the plurality of pixel electrodes.

13. An organic light-emitting display comprising:
a substrate including a first pixel region, a second pixel region spaced apart from the first pixel region in a horizontal direction, and a division region disposed between the first pixel region and the second pixel region;
an insulating layer disposed on the substrate and including a recess disposed in the division region, the insulating layer including a first inner side wall defining a first portion of the recess and having a straight-line shape and a second inner side wall extending from the first inner side wall, defining a second portion of the recess, and having a curved shape;
a plurality of pixel electrodes disposed on the insulating layer, including a first pixel electrode disposed in the first pixel region and a second pixel electrode disposed in the second pixel region;
a spacer disposed on a side wall of each of the pixel electrodes and the first inner side wall of the insulating layer;
a first organic emission layer disposed on the spacer in the first pixel region and the second pixel region;
a first cavity surrounded by the second inner side wall; and
a second cavity disposed between the first organic emission layer in the first pixel region and the first organic emission layer in the second pixel region,
wherein the first cavity and the second cavity are connected to each other.

14. The organic light-emitting display of claim 13, wherein a vertical level of a bottom surface of the first organic emission layer is lower than or substantially equal to a vertical level of a bottommost surface of the spacer.

15. The organic light-emitting display of claim 13, further comprising a second organic emission layer disposed on the first organic emission layer,
wherein the first organic emission layer includes a first stack, a second stack, and a first charge generation layer that are sequentially stacked,
the second organic emission layer includes a third stack, a fourth stack, and a second charge generation layer that are sequentially stacked, and
a vertical level of a bottom surface of the first organic emission layer is substantially equal to a vertical level of a bottom surface of the second organic emission layer.

16. The organic light-emitting display of claim 13, wherein a width of the first cavity is greater than a distance between side walls of the spacer facing each other in the division region.

17. The organic light-emitting display of claim 13, wherein the first organic emission layer includes a first portion disposed in the first pixel region and a second portion disposed in the second pixel region and disconnected in the division region from the first portion of the first organic emission layer.

18. The organic light-emitting display of claim 17, further comprising a common electrode disposed on the first organic emission layer,
wherein the common electrode continually extends from the first pixel region to the second pixel region.

19. An organic light-emitting display comprising:
a substrate including a first pixel region, a second pixel region spaced apart from the first pixel region in a horizontal direction, and a division region disposed between the first pixel region and the second pixel region;
a circuit device layer disposed on the substrate;
an insulating layer disposed on the circuit device layer and including a recess in the division region, the recess defined by a first inner side wall of the insulating layer adjacent to a top surface of the insulating layer and a second inner side wall of the insulating layer extending from the first inner side wall;
a plurality of pixel electrodes disposed on the insulating layer, and including a first pixel electrode in the first pixel region and a second pixel electrode in the second pixel region;
a spacer disposed on a side wall of each of the pixel electrodes and the first inner side wall of the insulating layer;
a first organic emission layer disposed on a top surface and a side wall of the spacer, the first organic emission layer continually extending in the horizontal direction in the first pixel region and the second pixel region and disconnected in the division region;
a second organic emission layer disposed on the first organic emission layer, the second organic emission layer disposed on a top surface and a side surface of the first organic emission layer;
a third organic emission layer disposed on the second organic emission layer, the third organic emission layer continually extending from the first pixel region to the second pixel region; and
a common electrode disposed on the third organic emission layer, the common electrode continually extending from the first pixel region to the second pixel region,
wherein the first inner side wall has a straight-line shape,
the second inner side wall has a concave shape, and
the spacer includes a material having an etch selectivity different than an etch selectivity of the insulating layer.

20. The organic light-emitting display of claim 19, wherein the first organic emission layer extends to a bottommost surface of the spacer.
